(19) United States
(12) Patent Application Publication
(10) Pub. No.: US 2009/0167358 A1
(43) Pub. Date: Jul. 2, 2009

(54) FULLY INTERRUPTIBLE DOMINO LATCH

(76) Inventor: Chayan Kumar SEAL, Austin, TX (US)

Correspondence Address: KED & ASSOCIATES, LLP;INTEL CORPORATION, P.O. BOX 221200, CHANTILLY, VA, 20153-1200, US

(21) Appl. No.: 11/966,241

(22) Filed: Dec. 28, 2007

(51) Int. Cl. H03K 19/096

(52) U.S. Cl. 326/98

(57) ABSTRACT

A domino latch is provided that comprises a forward path circuit and a feedback path circuit. The feedback path includes a plurality of keeper transistors, an inverter, and at least one interrupt transistor to cut off the feedback path circuit and prevent signal contention on the output node between the feedback path circuit and the forward path circuit.

### BACKGROUND

1. Field

Embodiments of the present invention may relate to domino logic circuits. More specifically, embodiments of the present invention may relate to a set dominant latch (SDL) or a reset dominant latch (RDL), also known as zero catcher or one catcher, respectively.

2. Background

Domino logic is a digital logic design methodology. Domino logic may be used in design of high speed digital electronics, such as computer processors, memories and other integrated circuits. Domino logic, or dynamic logic, may be distinguished from static logic in that domino logic uses a clock signal in implementation of combinational logic circuits.

Domino logic may include a precondition phase and an evaluation phase. An SDL may operate with precharge domino logic, whereas an RDL may operate with pre-discharge domino logic. During the evaluation phase, domino logic may either remain in the preconditioned state or convert to an opposite state. Domino logic may be converted into static logic using a domino to static converter, such as a set dominant latch (SDL) or as a reset dominant latch (RDL).

### BRIEF DESCRIPTION OF THE DRAWINGS

Arrangements and embodiments may be described in detail with reference to the following drawings in which like reference numerals refer to like elements and wherein:

FIG. 1 is a circuit diagram of a prior art domino latch in accordance with an example arrangement;

FIG. 2 is a circuit diagram of a domino latch in accordance with an example embodiment of the present invention; and

FIG. 3 is a circuit diagram of a domino latch in accordance with an example embodiment of the present invention.

### DETAILED DESCRIPTION

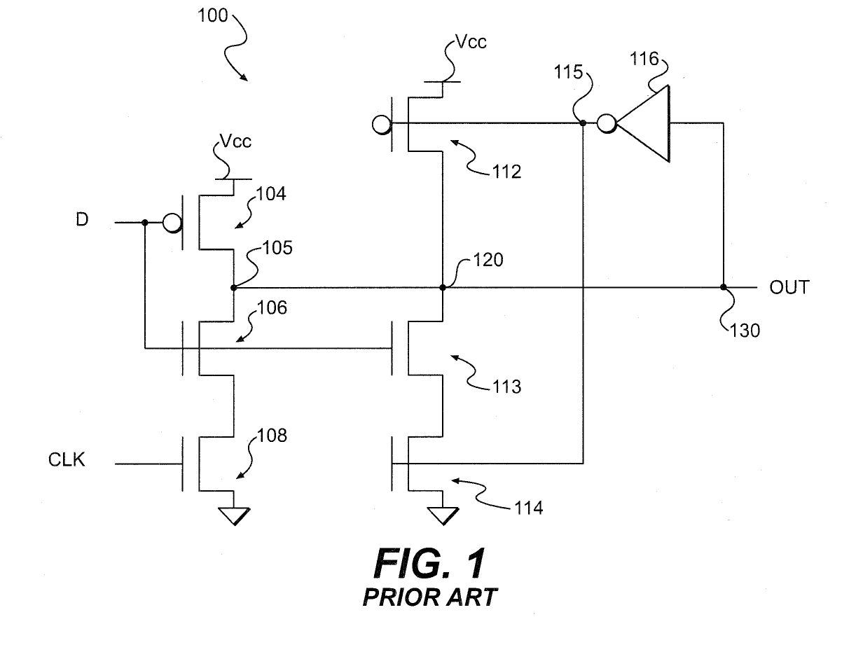

FIG. 1 is a circuit diagram of a prior art domino latch according to an example arrangement. Other arrangements may also be used. More specifically, FIG. 1 shows a domino logic dominant latch 100 that includes a forward path circuit and a feedback path circuit. The forward path circuit may include transistors 104, 106, 108, which may be field effect transistors (FETs) or metal oxide field effect transistors (MOSFETs).

The feedback path circuit may include transistors 112, 113, 114 and an inverter 116 (or NOT gate). The transistors 112, 113 and 114 may be FETs or MOSFETs. More specifically, the transistor 112 may be a P-channel MOSFET (or PMOS), and the transistors 113 and 114 may each be an N-channel MOSFET (or NMOS).

A gate of the transistor 112 may be coupled to a node 115 and to an output of the inverter 116. A source of the transistor 112 may be coupled to a voltage source Vcc and a drain of the transistor 112 may be coupled to a node 120, which corresponds to output node (OUT) 130.

A drain of the transistor 113 may be coupled to the node 120 and a source of the transistor 113 may be coupled to a drain of the transistor 114.

A gate of the transistor 114 may be coupled to the node 115 and to the output of the inverter 116. A source of the transistor 114 may be coupled to GROUND, and the drain of the transistor 114 may be coupled to the source of the transistor 113.

An input of the inverter 116 may be coupled to the output node 130, which corresponds to the node 120 and to the node 105 between the transistors 104 and 106. The output signal (OUT) is input to the inverter 116. The output of the inverter 116 is coupled to the node 115, to the gate of the transistor 112 and to the gate of the transistor 114.

As shown in FIG. 1, a data input D may be applied to a gate of the transistor 104, to a gate of the transistor 106 and to a gate of the transistor 113. Accordingly, when the data input is LOW, the transistors 106 and 113 are OFF and the output node 130 is not coupled to GROUND via the transistors 108 and 114. Accordingly, the output node 130 will attempt to go HIGH. On the other hand, when the output node 130 is HIGH and the data input is HIGH, then the transistors 106, 112 and 113 are ON. When the clock signal CLK goes HIGH, the transistor 108 is turned ON, and the output node 130 will attempt to go LOW. Thus, the transistor 106, which attempts to pull the output node 130 to a LOW state contends or fights with the transistor 112, which attempts to maintain the output node 130 at a HIGH state.

Contention may be a condition when two transistors from two different circuit paths (or path circuits) fight to force opposite logic values on a same logic node, such as the output node 130 of FIG. 1. The stronger of the two transistors may eventually overwhelm the weaker of the two transistors and write its logic value on the logic node. Contention may be a prevalent occurrence in a latch where a transistor in the forward path circuit tries to overwhelm a transistor in the feedback path circuit and write to the output node.

Logic design may try to eliminate or substantially reduce contention. One reason for this is that two transistors may drive opposing currents onto the same node until one transistor overwhelms the other transistor. This may result in considerably more logic delay and wasted power. Additionally, a low voltage operation may introduce uncertainty regarding a final (or steady state) logic value on the node because transistors weaken non-uniformly with lower voltages.

One way to eliminate or reduce contention in a latch is to cut off or interrupt the transistor in the feedback path circuit from writing to the logic node when the transistor in the forward path circuit is doing so, thereby making the latch “interruptible”. A latch may be “fully interruptible” if the transistor in the feedback path circuit can be cut off whenever the transistor in the forward path circuit attempts to write a logic 0 or a logic 1 value on the output node of the latch. The latch may be “half-interruptible” if the transistor of the feedback path circuit can be cut off during the write of only one of the two logic values, but not the other. The latch may be “non-interruptible” if the transistor of the feedback path circuit can not be cut off during either of the logic values. For example, FIG. 1 shows a half-interruptible latch because the latch can cut off the feedback path circuit only during a logic 1 write on the latch output node through the PMOS transistor 104, but the latch can not cut off the feedback path circuit during a logic 0 write on the latch output node through the NMOS transistor 106.

Embodiments of the present invention may provide a domino latch that may include a forward path circuit having a plurality of transistors and a feedback path circuit having at least one keeper transistor, at least one interrupt transistor (or cut-off transistor) and an inverter. The interrupt transistor may render the dominant latch fully interruptible.

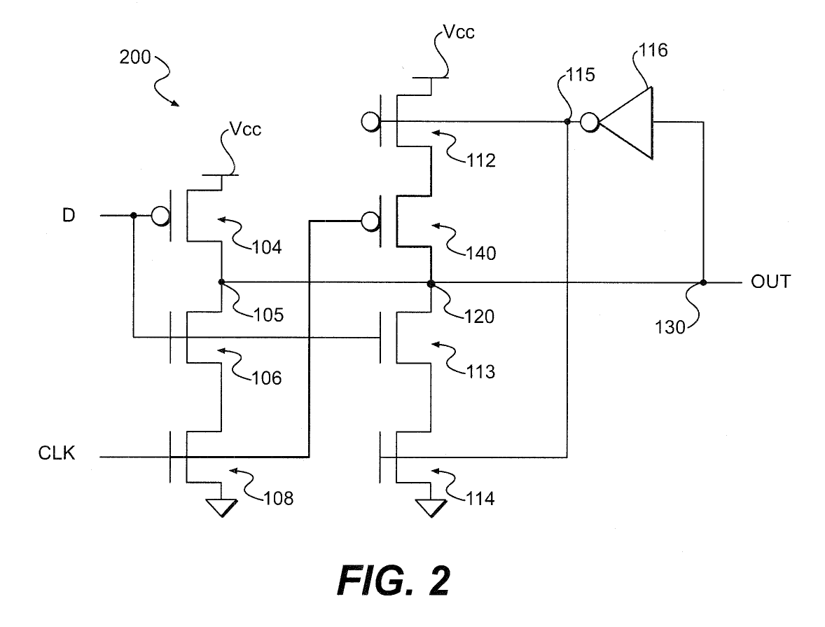

FIG. 2 is a circuit diagram of a domino latch in accordance with an example embodiment of the present invention. Other embodiments and configurations are also within the scope of the present invention.

More specifically, FIG. 2 shows a fully interruptible domino logic set dominant latch (SDL) 200. The latch 200 may include a forward path circuit and a feedback path circuit. As will be described below, the feedback path circuit includes an interrupt transistor 140 (or cut off transistor) to interrupt the feedback path circuit during an evaluation phase so as to prevent contention between the feedback path circuit and the forward path circuit making the latch 200 fully interruptible.

The forward path circuit may include transistors 104, 106, 108, which may be metal oxide field effect transistors (MOSFETs) or FETs. More specifically, the transistor 104 may be a P-channel MOSFET (or PMOS), and the transistors 106 and 108 may be N-channel MOSFETs (or NMOS). The transistor 104 may also be called pull-up transistor and the transistors 106 and 108 may also be called pull-down transistors.

A source of the transistor 104 may be coupled to the voltage source Vcc, and a drain of the transistor 104 may be coupled through the node 105 to a drain of the transistor 106. A source of the transistor 106 may be coupled to a drain of the transistor 108. The source of the transistor 108 may be coupled to GROUND.

The feedback path circuit may include transistors 112, 113, 114 and 140 and an inverter 116 (or NOT gate). The transistors 112, 113, 114 and 140 may be metal oxide field effect transistors (MOSFETs) or FETs. More specifically, the transistors 112 and 140 may each be a P-channel MOSFET (or PMOS), and the transistors 113 and 114 may each be an N-channel MOSFET (or NMOS).

The transistor 112 may be referred to as a P-keeper transistor since a P-keeper transistor holds a “1” on a node as compared to an N-keeper transistor that holds a “0” on a node. The keeper transistor 112 may attempt to maintain the output node 130 at a HIGH state during the evaluation phase. The gate of the transistor 112 may be coupled to the node 115 and to the output of the inverter 116. The source of the transistor 112 may be coupled to the voltage source Vcc and a drain of the transistor 112 may be coupled to a source of the transistor 140. A drain of the transistor 140 may be coupled to the node 120, which also corresponds to the nodes 105 and 130.

An input of the inverter 116 may be coupled to the output node 130. The output signal (OUT) at the output node 130 is input to the inverter 1 16. An output of the inverter 116 may be coupled through the node 115 to the gate of the transistor 112 and to the gate of the transistor 114.

A data input D may be applied to a gate of the transistor 104 and to a gate of the transistor 106 and to a gate of the transistor 113. A clock signal CLK may be applied to a gate of the transistor 108 and to a gate of the transistor 140. A source of the transistor 108 may be coupled to GROUND.

The PMOS transistor 104 and the NMOS transistors 106 and 108 may form the forward path circuit of the set dominant latch. The inverter 116, the PMOS transistors 112 and 140 and the NMOS transistors 113 and 114 may form the feedback path of the fully interruptible set dominant latch. Although not shown, embodiments of the present invention may include the feedback path circuit and the forward path circuit both sharing a common transistor.

An SDL may operate with precharge domino logic which may include a precharge phase (in which the clock signal CLK is LOW) and the evaluation phase (in which the clock signal CLK is HIGH). In the pre-charge phase, the data input D may be HIGH, the clock signal CLK may be de-asserted (LOW) and a value of a state on the output node 130 may be retained by the latch 200. When the clock signal CLK transitions HIGH, the latch 200 enters the evaluation phase. In the evaluation phase, if the data input D is LOW, the output node 130 will attempt to go HIGH. In this scenario, the NMOS transistors 106 and 113 may turn OFF thereby disconnecting the NMOS transistors 108 and 114 from the output node 130. This cuts off the path from the output node 130 to GROUND by eliminating contention with the rise transition of the output OUT.

On the other hand, in the evaluation phase, if the data input D is HIGH, the NMOS transistor 106 turns ON and the PMOS transistor 104 turns OFF. The clock signal CLK may be asserted during the evaluation phase, which turns ON the NMOS transistor 108 and turns OFF the PMOS transistor 140. The turning OFF of the PMOS transistor 140 (or interrupt or cut-off transistor) disconnects the output node 130 from the transistor 112 and the voltage source VCC, thereby allowing the output node 130 to reset to LOW without contention from the transistors 104 and 112. The PMOS transistor 140 therefore serves as an interrupt transistor in the evaluation phase to cut off or interrupt the feedback path circuit and prevent contention on the output node between the forward path circuit and the reverse path circuit.

Embodiments of the present invention may provide a fully interruptible SDL 200 that includes an interrupt transistor in a feedback path circuit to turn OFF during a domino logic evaluation phase in order to disable or prevent signal contention on the output node between the feedback path circuit and the forward path circuit.

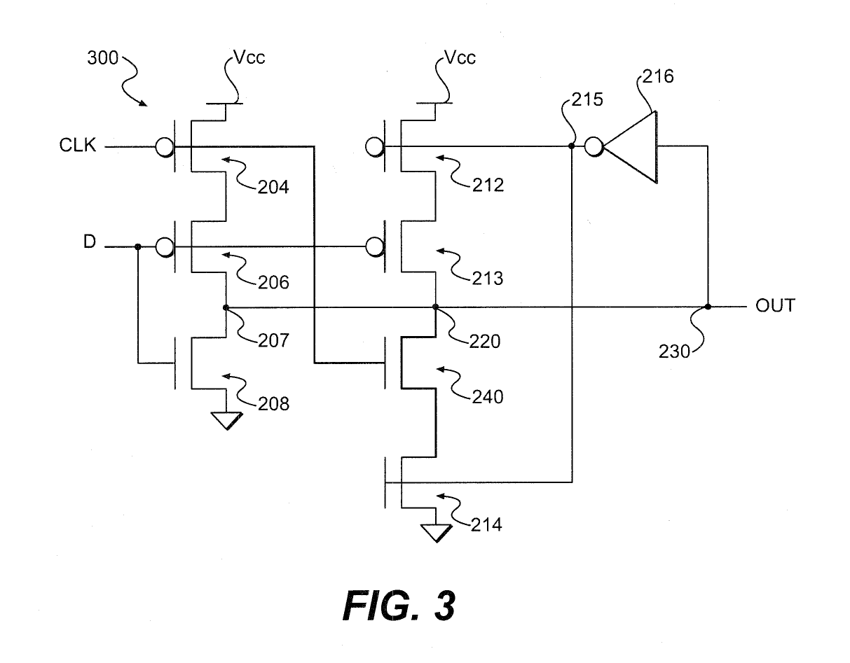

FIG. 3 is a circuit diagram of a domino latch in accordance with an example embodiment of the present invention. More specifically, FIG. 3 shows a fully interruptible reset dominant latch (RDL) 300. The latch 300 may include a forward path circuit and a feedback path circuit. As will be described below, the feedback path circuit includes an interrupt transistor 240 to disable or prevent contention of the feedback path circuit with the forward path circuit making the latch 300 fully interruptible.

The forward path circuit may include transistors 204, 206, 208, which may be metal oxide field effect transistors (MOSFETs) or FETs. More specifically, the transistors 204 and 206 may each be a P-channel MOSFET (or PMOS), and the transistor 208 may be an N-channel MOSFET (or NMOS).

A source of the transistor 204 may be coupled to the voltage source Vcc. A drain of the transistor 204 may be coupled to a source of the transistor 206. The drain of the transistor 206 may be coupled through a node 207 to a drain of the transistor 208. A source of the transistor 208 may be coupled to GROUND.

The feedback path circuit may include transistors 212, 213, 214 and 240 and an inverter 216 (or NOT gate). The transistors 212, 213, 214 and 240 may be metal oxide field effect transistors (MOSFETs) or FETs. More specifically, the transistors 212 and 213 may each be a P-channel MOSFET (or PMOS), and the transistors 214 and 240 may each be an N-channel MOSFET (or NMOS).

The transistor 212 may be referred to as a P-keeper transistor. The keeper transistor 212 may attempt to maintain the output node 230 at a HIGH state during the evaluation phase. The gate of the transistor 212 may be coupled to the node 215 and to an output of the inverter 216. The source of the transistor 212 may be coupled to the voltage source Vcc and the drain of the transistor 212 may be coupled to a source of the transistor 213.

A drain of the transistor 213 may be coupled to the node 220, which also corresponds to the nodes 207 and 230. A drain of the transistor 240 is coupled to the node, and a source of the transistor 240 may be coupled to the drain of the transistor 214. The source of the transistor 214 is coupled to GROUND.

An input of the inverter 216 may be coupled to the output node 230. The output signal (OUT) at the output node 230 is input to the inverter 216. An output of the inverter 216 may be coupled through the node 215 to the gate of the transistor 212 and to a gate of the transistor 214.

A data input D may be applied to a gate of the transistor 206 and to a gate of the transistor 208 and to a gate of the transistor 213. A clock signal CLK may be applied to a gate of the transistor 204 and to a gate of the transistor 240.

The PMOS transistors 204, 206 and the NMOS transistor 208 may form the forward path circuit of the reset dominant latch. The inverter 216, the PMOS transistors 212 and 213 and the NMOS transistors 214 and 240 may form the feedback path circuit of the fully interruptible reset dominant latch. Although not shown, embodiments of the present invention may include a feedback path circuit and a forward path circuit that include a common transistor.

An RDL may operate with precharge domino logic which may include a pre-discharge phase and an evaluation phase. In the pre-discharge phase, the data input D may be LOW, the clock signal CLK may be asserted (HIGH) and a value of a state on the output node 230 may be retained by the latch 300. When the clock signal CLK transitions LOW, the latch 300 enters the evaluation phase.

In the evaluation phase, the clock signal may be de-asserted, which turns ON the transistor 204 and turns OFF the transistor 240. If the data input D is HIGH, the PMOS transistors 206 and 213 turn OFF, the NMOS transistor 208 is turned ON and the output node 230 will attempt to go LOW.

On the other hand, in the evaluation phase, if the data input D is LOW, the NMOS transistors 206 and 213 turn ON and the NMOS transistor 208 turns OFF. The clock signal CLK may be de-asserted during the evaluation phase, which turns ON the PMOS transistor 204 and turns OFF the NMOS transistor 240. The turning OFF of the NMOS transistor 240 (or interrupt or cut-off transistor) disconnects the output node 230 from the transistor 214, thereby allowing the NMOS transistor 208 to reset the output node 230 to LOW without contention from the transistors 208 and 214. The NMOS transistor 240 therefore serves as an interrupt transistor in the evaluation phase to cut off the feedback path circuit and prevent contention on the output node between the forward path circuit and the feedback path circuit.

Embodiments of the present invention may provide a fully interruptible RDL 300 that includes an interrupt transistor in a feedback path circuit to turn OFF during a domino logic evaluation phase in order to disable or prevent signal contention on the output node between the feedback path circuit and the forward path circuit.

Although not shown, embodiments of the present invention may include a feedback path circuit and a forward path circuit that both share a common transistor. Further, embodiments of the present invention may include multiple inputs including multiple clocks. Further, embodiments of the present invention may also include a plurality of interrupt transistors to cut of the feedback path during the evaluation phase.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A domino latch comprising:
a forward path circuit to receive a data input signal and a clock signal, the forward path circuit including a plurality of transistors; and
a feedback path circuit including a plurality of keeper transistors and at least one interrupt transistor to cut off the feedback path circuit and prevent contention on an output node between the forward path circuit and the feedback path circuit, wherein the plurality of keeper transistors includes a first keeper transistor and a second keeper transistor, the first keeper transistor to couple between the output node and the second keeper transistor, the second keeper transistor to couple between the first keeper transistor and ground, and a gate of the first keeper transistor to receive the data input signal.

2. The domino latch of claim 1, wherein the interrupt transistor is to be turned off in a domino evaluation phase to disable any contention of the feedback path circuit with the forward path circuit.

3. The domino latch of claim 1, wherein the domino latch comprises a set dominant latch.

4. The domino latch of claim 3, wherein the interrupt transistor comprises a p-channel field effect transistor.

5. The domino latch of claim 17, wherein the domino latch comprises a reset dominant latch.

6. The domino latch of claim 17, wherein the interrupt transistor comprises an n-channel field effect transistor.

7. The domino latch of claim 1, wherein the domino latch comprises a fully interruptible domino latch.

8. The domino latch of claim 1, wherein a gate of the interrupt transistor to receive the clock signal.

9. A domino latch comprising:
a forward path circuit to receive a data input signal and a clock signal and to provide an output signal on an output node; and
a feedback path circuit including a plurality of keeper transistors and at least one n-channel interrupt transistor to cut off the feedback path circuit during an evaluation phase, the latch to be interruptible between the forward path circuit and the feedback path circuit.

10. The domino latch of claim 9, wherein the n-channel interrupt transistor to prevent signal contention on the output node between the forward path circuit and the feedback path circuit.

11-12. (canceled)

13. The domino latch of claim 9, wherein the domino latch comprises a reset dominant latch.

14. The domino latch of claim 13, wherein the n-channel interrupt transistor comprises an n-channel field effect transistor.

15. The domino latch of claim 9, wherein a gate of the n-channel interrupt transistor to receive the clock signal.

16. The domino latch of claim 9, wherein the plurality of keeper transistors includes a first keeper transistor, a second keeper transistor and a third keeper transistor, the first transistor to couple between a voltage source and the second keeper transistor, the second keeper transistor to couple between the first keeper transistor and the output node, the third keeper transistor to couple between the at least one n-channel interrupt transistor and ground, and a gate of the second keeper transistor to receive the data input signal.

17. A domino latch comprising:
a forward path circuit to receive a data input signal and a clock signal, the forward path circuit including a plurality of transistors; and
a feedback path circuit including a plurality of keeper transistors and at least one interrupt transistor to cut off the feedback path circuit and prevent contention on an output node between the forward path circuit and the feedback path circuit, wherein the plurality of keeper transistors includes a first keeper transistor, a second keeper transistor and a third keeper transistor, the first transistor to couple between a voltage source and the second keeper transistor, the second keeper transistor to couple between the first keeper transistor and the output node, the third keeper transistor to couple to the interrupt transistor and ground, a gate of the second keeper transistor to receive the data input signal and a gate of the interrupt transistor to receive the clock signal.

18. The domino latch of claim 17, wherein the interrupt transistor is a different transistor than any one of the first, second or third keeper transistors.

19. The domino latch of claim 1, wherein the first keeper transistor and one of transistors of the forward path circuit to turn OFF and disconnect the output node from each of the second keeper transistor and another one of the transistors of the forward path circuit.
